(19) United States
(12) Patent Application Publication
(10) Pub. No.: US 2020/0286660 A1
(43) Pub. Date: Sep. 10, 2020

(54) ON-PACKAGE VERTICAL INDUCTORS AND TRANSFORMERS FOR COMPACT 5G MODULES

(71) Applicant: Intel Corporation, Santa Clara, CA (US)

(72) Inventor: Telesphor KAMGAING, Chandler, AZ (US)

(21) Appl. No.: 16/291,328

(22) Filed: Mar. 4, 2019

(51) Int. Cl. H01F 17/00; H05K 1/18; H05K 1/02; H05K 1/16; H01L 23/00; H01L 23/498; H01L 23/64

(52) U.S. Cl. CPC H01F 17/0013; H01L 2924/19103; H05K 1/0243; H05K 1/165; H01L 24/16; H01L 23/49816; H01L 23/645; H05K 2201/10098; H05K 2201/10378; H01F 2017/0073; H01F 2017/002; H01L 2224/16225; H01L 2924/15311; H01L 2924/19042; H05K 1/181

(57) ABSTRACT

In an embodiment, an inductor comprises a first trace, where the first trace has a first end and a second end, and where the first trace extends along a first plane, and a first conductive path over the first end of the first trace, where the first conductive path extends along a second plane that is substantially orthogonal to the first plane. In an embodiment, the inductor further comprises a second conductive path over the second end of the first trace, where the second conductive path extends along a third plane that is substantially parallel to the second plane, and a second trace over the first conductive path, where the second trace extends along a fourth plane that substantially parallel to the first plane. In an embodiment, the inductor further comprises a third trace over the second conductive path, where the third trace extends along the fourth plane.

### TECHNICAL FIELD

Embodiments of the present disclosure relate to electronic packaging, and more particularly, to electronic packages with vertical inductors and transformers and methods of forming such electronic packages.

### BACKGROUND

Inductors play a major role in radio frequency (RF) integrated circuits used in modern wireless communication systems. Inductors are widely used in both transceivers and RF front end (RFFE) circuits. One major challenge for inductors, however, is that inductors do not scale with technology node. As such, inductors occupy relatively large real estate, either on the chip or on the package substrate. As technology progresses to next generation devices that include 5G compatibility, more filters will be integrated using high performance inductors on package. Accommodating all inductors on the available real estate is a major challenge for high density integration.

Some current approaches to improving the inductance of inductors is to use a planar spiral architecture. Such layouts are still space intensive. Particularly, pads needed for connecting stacked planar inductors are large (e.g., 60 μm or greater). This increases the footprint of the inductor and also reduces inductance since a larger portion of the core is occupied by the pad. Furthermore, spiral inductors provide a non-symmetric inductor. This makes it difficult to locate the electrical center of the inductor, which is critical for reducing phase and amplitude imbalances in differential RF circuits. Additionally, area below the planar inductors needs to be voided of metal, leading to low substrate utilization or an increase in the overall thickness of the module.

### BRIEF DESCRIPTION OF THE DRAWINGS

FIG. 1A is a perspective view illustration of a vertically oriented inductor with a single turn, in accordance with an embodiment.

FIG. 1B is a perspective view illustration of a vertically oriented inductor that is a solenoid, in accordance with an embodiment.

FIG. 1C is a perspective view illustration of a vertically oriented transformer that includes a pair of vertically oriented single turn inductors, in accordance with an embodiment.

FIG. 2A is a perspective view illustration of a vertically oriented multi-turn inductor, in accordance with an embodiment.

FIG. 2B is a plan view illustration of a first layer of the multi-turn inductor of FIG. 2A, in accordance with an embodiment.

FIG. 2C is a plan view illustration of a second layer of the multi-turn inductor of FIG. 2A, in accordance with an embodiment.

FIG. 2D is a plan view illustration of a third layer of the multi-turn inductor of FIG. 2A, in accordance with an embodiment.

FIG. 2E is a plan view illustration of a fourth layer of the multi-turn inductor of FIG. 2A, in accordance with an embodiment.

FIG. 2F is a perspective view illustration of a vertically oriented transformer that includes a pair of multi-turn inductors, in accordance with an embodiment.

FIG. 3A is a cross-sectional illustration of a vertically oriented inductor embedded in a package substrate, in accordance with an embodiment.

FIG. 3B is a cross-sectional illustration of a vertically oriented multi-turn inductor embedded in a package substrate, in accordance with an embodiment.

FIG. 4A is perspective view illustration of a symmetric multi-turn inductor, in accordance with an embodiment.

FIG. 4B is a perspective view illustration of a symmetric multi-turn inductor with a trench via, in accordance with an embodiment.

FIG. 4C is a plan view illustration of a first layer of the multi-turn inductor of FIG. 4B, in accordance with an embodiment.

FIG. 4D is a plan view illustration of a second layer of the multi-turn inductor of FIG. 4B, in accordance with an embodiment.

FIG. 4E is a plan view illustration of a symmetric multi-turn inductor with a center tap, in accordance with an embodiment.

FIG. 5A is a cross-sectional illustration of a package core, in accordance with an embodiment.

FIG. 5B is a cross-sectional illustration after through core vias are disposed through the package core, in accordance with an embodiment.

FIG. 5C is a cross-sectional illustration after first layers are disposed over the vias, in accordance with an embodiment.

FIG. 5D is a cross-sectional illustration after a dielectric layer is disposed over the package core, in accordance with an embodiment.

FIG. 5E is a cross-sectional illustration after openings are disposed in the dielectric layer to expose the first layers, in accordance with an embodiment.

FIG. 5F is a cross-sectional illustration after vias are disposed in the openings, in accordance with an embodiment.

FIG. 5G is a cross-sectional illustration after a second layer is disposed over the vias, in accordance with an embodiment.

FIG. 5H is a cross-sectional illustration after a second dielectric layer is disposed over the second layer, in accordance with an embodiment.

FIG. 6A is a cross-sectional illustration of a single turn inductor that includes through core vias, in accordance with an embodiment.

FIG. 6B is a cross-sectional illustration of a multi-turn inductor that includes through core vias, in accordance with an embodiment.

FIG. 7 is a schematic of a filter that may include a vertically oriented inductor or transformer, in accordance with an embodiment.

FIG. 8 is a cross-sectional illustration of an electronic system that comprises vertically oriented inductors, in accordance with an embodiment.

FIG. 9 is a schematic of a computing device built in accordance with an embodiment.

### EMBODIMENTS OF THE PRESENT DISCLOSURE

Described herein are electronic packages with vertically oriented inductors and transformers and methods of forming such electronic packages, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, currently available inductor architectures suffer from large footprints and poor symmetry. Accordingly, embodiments disclosed herein provide vertically oriented inductors. The vertically oriented inductors have several advantages. One advantage is that the vertically oriented inductors have a higher quality factor Q compared to planar inductors. This is because there is no need for a large pad in the middle of the conductive loop. Furthermore, the lithographic processes used in some embodiments to fabricate the vertically oriented inductors allows for thicker conductive paths. This reduces resistance of the inductor, and therefore, improves the quality factor Q. Furthermore, the use of lithographically defined inductors enables the creation of compact inductors, and therefore, compact filters and modules. Additionally, the use of vertically oriented inductors utilizes more layers of the package. This provides an increased metal density compared to planar inductors. Inductors in accordance with embodiments disclosed herein also are symmetric. This reduces the complexity of reducing imbalances in differential circuits. Such vertically oriented inductors also provide simple integration of N:N transformers (where N is the number of turn ratio between the primary and the secondary sides of the transformer).

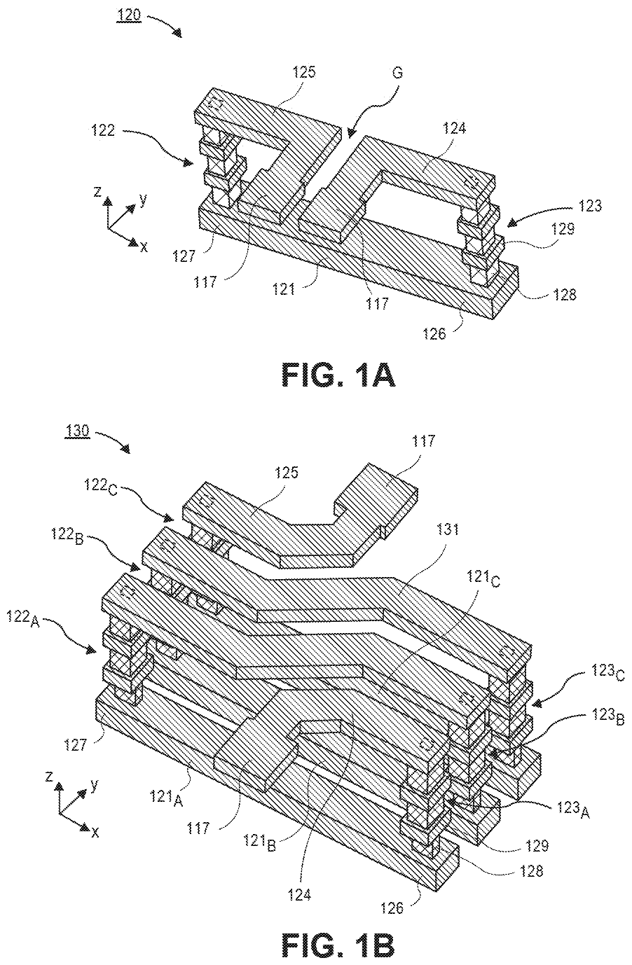

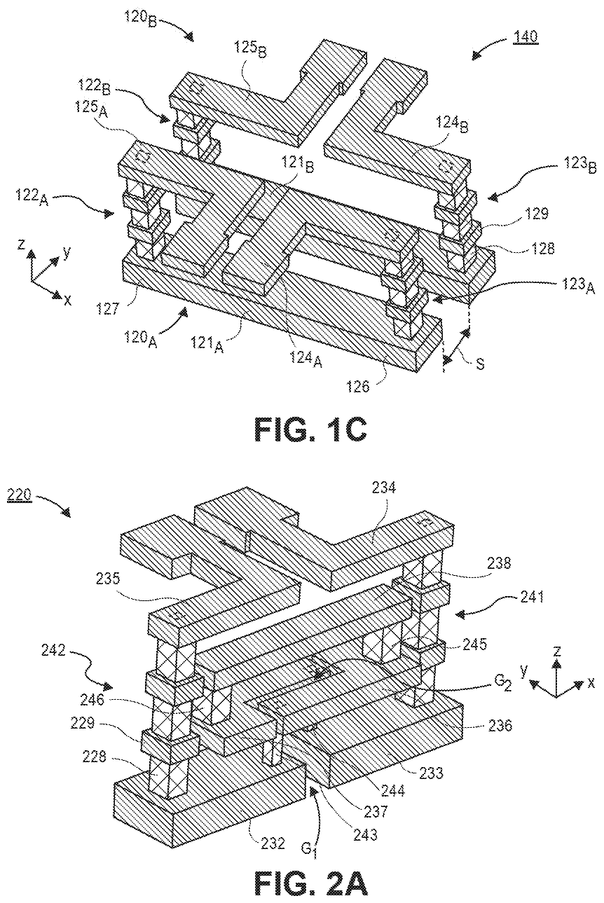

Referring now to FIG. 1A, a perspective view illustration of a vertically oriented single turn inductor 120 is shown, in accordance with an embodiment. In an embodiment, the inductor 120 may be embedded in an organic substrate (e.g., build-up layers of a package substrate). However, the organic package is omitted from FIG. 1A in order to not obscure aspects of the illustrated embodiment.

In an embodiment, the inductor 120 may comprise a single turn that is fabricated into a plurality of layers of the organic substrate. For example, a first trace 121 may be on a first layer of the organic substrate, and a second trace 124 and a third trace 125 may be on a different layer of the organic substrate. The second trace 124 may be electrically coupled to a first end 126 of the first trace 121 by a first conductive path 123 through one or more layers of the organic substrate, and the third trace 125 may be electrically coupled to a second end 127 of the first trace 121 by a second conductive path 122 through one or more layers of the organic substrate. In an embodiment, the first conductive path 123 and the second conductive path 122 may comprise alternating vias 128 and pads 129. In an embodiment, the vias 128 may be lithographically defined vias.

In an embodiment, the first trace 121 may extend along a first plane. For example, the first plane may be along the X-Y plane at a first Z-height. In an embodiment, the first conductive path 123 and the second conductive path 122 may extend along second planes that are substantially orthogonal to the first plane. For example, the first conductive path 123 may extend along the Z-Y plane at a first X-position, and the second conductive path 122 may extend along the Z-Y plane at a second X-position. In an embodiment, the second trace 124 and the third trace 125 may extend along a third plane that is substantially parallel to the first plane. For example, the third plane may be along the X-Y plane at a second Z-height.

In an embodiment, the inductor loop (e.g., comprising the first trace 121, the first conductive path 123, the second conductive path 122, portions of the second trace 124, and portions of the third trace 125) may be substantially within an X-Z plane. Accordingly, the inductor 120 may be referred to as being “vertically oriented” since the turn is executed in the Z-direction. This is in contrast to existing planar inductors described above where the turn is implemented in the X-Y plane.

In an embodiment, the inductor may be referred to as an open loop. That is, the turn does not form a complete loop. For example, inductor 120 may comprise a gap G between the second trace 124 and the third trace 125. In some embodiments, the second trace 124 and the third trace 125 may comprise portions that extend in the Y-direction. The portions may include pads 117 for providing connections to the inductor 120. In contrast to planar inductors, such as those described above, the pads are located outside of the open loop, and therefore, do not reduce the inductance of the inductor 120.

Referring now to FIG. 1B, a perspective view illustration of a vertically oriented solenoid 130 is shown, in accordance with an embodiment. In an embodiment, the solenoid 130 may comprise a plurality of turns adjacent to each other in the Y-direction. The solenoid 130 may include a plurality of first traces 121. For example, the solenoid 130 illustrated in FIG. 1B comprises three first traces 121_{A-C}. In an embodiment, each of the first traces 121 may have a first end 126 and a second end 127. In an embodiment, a first conductive path 123_{A-C} may be positioned over the first ends 126 of each first trace 121_{A-C}, and a second conductive path 122_{A-C} may be positioned over the second ends 127 of each first trace 121_{A-C}. Similar to FIG. 1A, the first conductive paths 123_{A-C} and the second conductive paths 122_{A-C} may comprise alternating vias 128 and pads 129.

In an embodiment, the solenoid 130 may comprise a plurality of bridge traces 131. In an embodiment, each bridge trace 131 may electrically couple a first conductive path 123 to a second conductive path 122 on a neighboring first trace 121. For example, a bridge trace 131 may electrically couple first conductive path 123_{C} to second conductive path 122_{B}.

In an embodiment, the solenoid 130 may also comprise a second trace 124 and a third trace 125. The second trace 124 may comprise a pad 117 for providing a first connection to the solenoid 130, and the third trace 125 may comprise a pad 117 for providing a second connection to the solenoid 130.

Referring now to FIG. 1C, a perspective view illustration of a vertically oriented transformer 140 is shown, in accordance with an embodiment. In an embodiment, the vertically oriented transformer 140 may comprise a first vertically oriented inductor 120_{A} proximate to a second vertically oriented inductor 120_{B}. For example, the first vertically oriented inductor 120_{A} may be spaced apart from the second vertically oriented inductor 120_{B} by a distance S. In an embodiment, the transformer 140 has a 1:1 impedance transformation ratio. However, it is to be appreciated that other impedance transformation ratios are also possible by changing dimensions of one of the inductors 120_{A} or 120_{B}.

In an embodiment, the vertically oriented inductors 120_{A} and 120_{B} may be substantially similar to the inductor 120 described above with respect to FIG. 1A. For example, each of the inductors 120_{A} and 120_{B} may comprise a first trace 121_{A}, 121_{B}, first conductive paths 123_{A}, 123_{B}, second conductive paths 122_{A}, 122_{B}, second traces 124_{A}, 124_{B}, and third traces 125_{A}, 125_{B}.

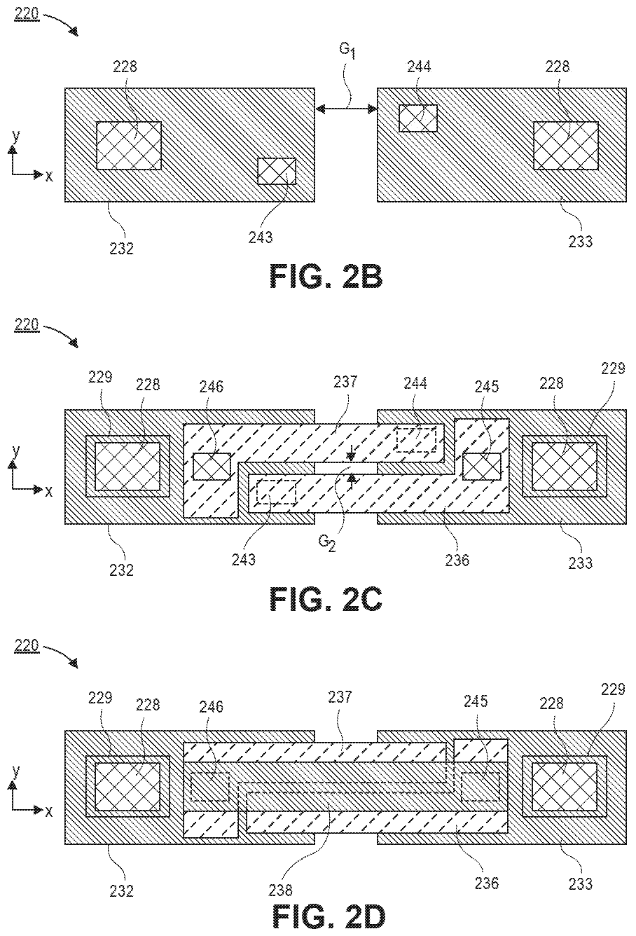

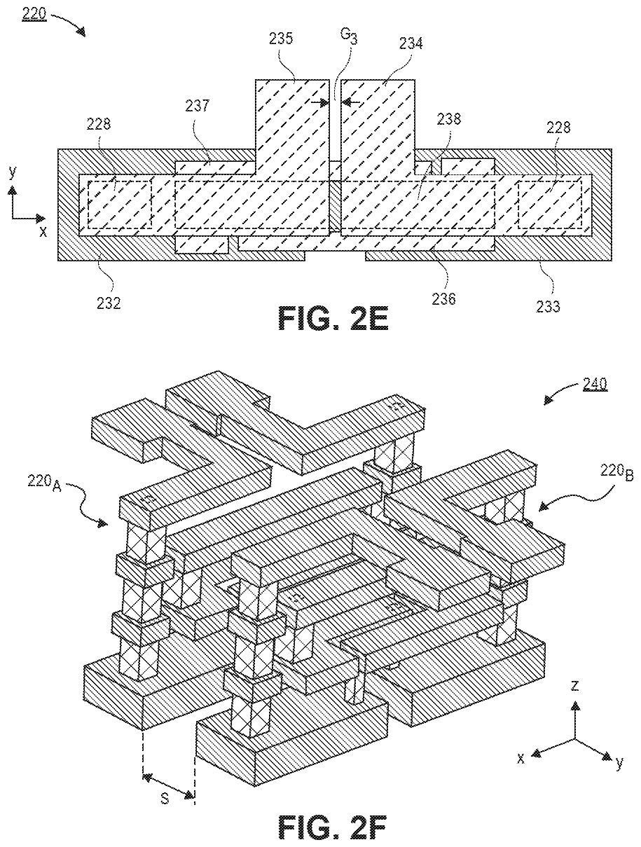

Referring now to FIG. 2A, a perspective view illustration of a vertically oriented multi-turn inductor 220 is shown, in accordance with an embodiment. In an embodiment, the first turn may comprise a first trace 232, a second trace 233, a first conductive path 241 over the second trace 233, a second conductive path 242 over the first trace 232, a third trace 234 over the first conductive path 241, and a fourth trace 235 over the second conductive path 242. The first conductive path 241 and the second conductive path 242 may comprise alternating vias 228 and pads 229.

In an embodiment, the first turn may be substantially similar to the open loop of the inductor 120 in FIG. 1A, with the exception that the first trace 121 is replaced with a first trace 232 and a second trace 233. In an embodiment, a gap G₁ may separate the first trace 232 from the second trace 233.

In an embodiment, the second turn may comprise a first via 243, a second via 244, a fifth trace 236, a sixth trace 237, a third via 245, a fourth via 246, and a seventh trace 238. In an embodiment, the second turn may be electrically coupled to the first turn by the first via 243 and the second via 244. For example, the first via 243 electrically couples the first trace 232 to the fifth trace 236, and the second via 244 electrically couples the second trace 233 to the sixth trace 237

In an embodiment, the fifth trace 236 and the sixth trace 237 are positioned in the same plane and are spaced apart from each other by a second gap G₂. In an embodiment, the fifth trace 236 and the sixth trace 237 have complementary surfaces. For example, in FIG. 2A the fifth trace 236 and the sixth trace 237 are “complimentary L-shapes”. However, any complementary shape may be used for the fifth trace 236 and the sixth trace 237. In an embodiment, the fifth trace 236 and the sixth trace 237 both extend over the first gap G₁ between the first trace 232 and the second trace 233. Accordingly, the fifth trace 236 and the sixth trace 237 enable a cross-over connection that allows for the formation of the second turn.

In an embodiment, the first turn and the second turn of the vertically oriented multi-turn inductor 220 are substantially within a first plane. For example, the first turn is along an X-Z plane at a first Y-location and the second turn is within the first turn along the first plane. Accordingly, inductance is improved by providing multiple turns without increasing the footprint of the inductor 220.

Referring now to FIGS. 2B-2E a series of plan view illustrations of the various layers of the inductor 220 in FIG. 2A are shown, in order to more clearly illustrate the layout of the various components.

Referring now to FIG. 2B, a plan view illustration of a first layer of inductor 220 is shown, in accordance with an embodiment. As shown, the first layer comprises the first trace 232 and the second trace 233. In an embodiment, the first trace 232 may be spaced apart from the second trace 233 by a first gap G₁. A via 228 of the conductive path 241 may be positioned over the second trace 233, and a via 228 of the second conductive path 242 may be positioned over the first trace 232. In an embodiment, the first via 243 may be positioned over the first trace 232 proximate to the first gap G₁, and the second via 244 may be positioned over the second trace proximate to the first gap G₁. In order to provide the cross-over, the first via 243 may be offset in Y-direction from the second via 244.

Referring now to FIG. 2C, a plan view illustration of a second layer of the inductor 220 is shown, in accordance with an embodiment. In an embodiment, the second layer may comprise the fifth trace 236 and the sixth trace 237. As shown, the fifth trace 236 and the sixth trace 237 may extend across the first gap G₁. The fifth trace 236 and the sixth trace 237 may have a complimentary shape and be spaced apart from each other by a second gap G₂. The fifth trace 236 may electrically couple the first via 243 to the third via 245, and the sixth trace 237 may electrically couple the second via 244 to the fourth via 246. In an embodiment, the second layer may also comprise pads 229 and vias 228 of first conductive path 241 and second conductive path 242. In an embodiment, the fifth trace 236 and the sixth trace 237 may re-rout the second turn so that the third via 245 and the fourth via 246 are aligned. That is, the third via 245 and the fourth via 246 may be substantially aligned in the Y-direction.

As shown in FIG. 2C, the shading of the components of the second layer is different than the shading of the components of the first layer for clarity. However, it is to be appreciated that the components (including the vias) may all be formed from the same conductive material (e.g., copper).

Referring now to FIG. 2D, a plan view illustration of a third layer of the inductor 220 is shown, in accordance with an embodiment. In an embodiment, the third layer may comprise the seventh trace 238. The seventh trace 238 may electrically couple the third via 245 to the fourth via 246 in order to complete the second turn. In an embodiment, the third layer may also comprise pads 229 and vias 228 of first conductive path 241 and second conductive path 242.

Referring now to FIG. 2E, a plan view illustration of a fourth layer of the inductor 220 is shown, in accordance with an embodiment. In an embodiment, the fourth layer may comprise the third trace 234 and the fourth trace 235. In an embodiment, the third trace 234 and the fourth trace 235 may extend towards each other and be separated by a third gap G₃.

As shown in FIGS. 2A-2E, the multi-turn inductor 220 include two turns.

However, it is to be appreciated that additional turns may also be formed in a single plane. The inclusion of additional turns may be implemented by increasing the number of layers and providing similar cross-over connections for each successive turn. Additionally, it is to be appreciated that a plurality of multi-turn inductors 220 may be connected in series to form a solenoid. Such a solenoid may be similar to the solenoid illustrated in FIG. 1B, with the exception that more than one turn may be included per plane.

Referring now to FIG. 2F, a perspective view illustration of a vertically oriented transformer 240 is shown, in accordance with an embodiment. In an embodiment, the vertically oriented transformer 240 may comprise a first vertically oriented inductor 220A proximate to a second vertically oriented inductor 220B. For example, the first vertically oriented inductor 220A may be spaced apart from the second vertically oriented inductor 220B by a distance S. In an embodiment, the transformer 240 has a 1:1 impedance transformation ratio. However, it is to be appreciated that other impedance transformation ratios are also possible by changing dimensions of one of the inductors 220A or 220B. In an embodiment, the vertically oriented inductors 220A and 220B may be substantially similar to the inductor 220 described above with respect to FIGS. 2A-2E.

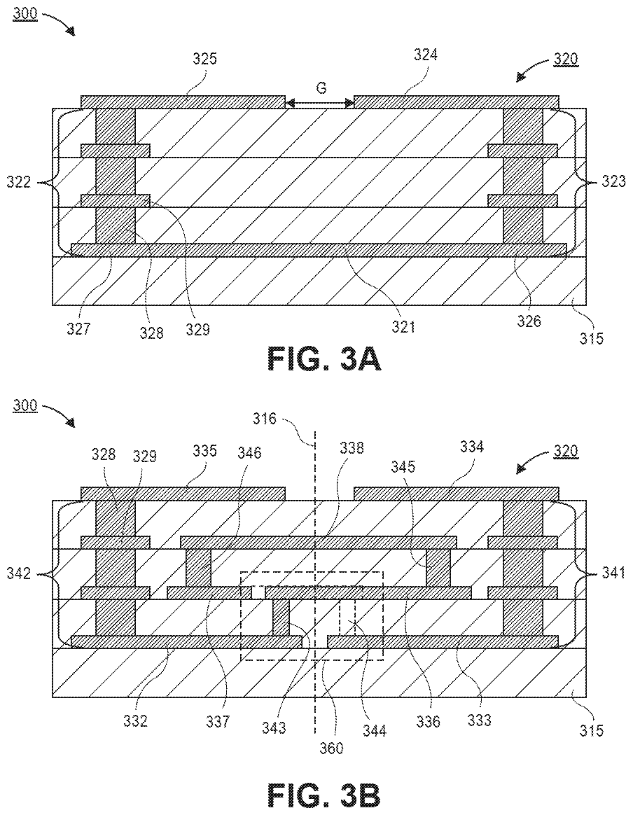

Referring now to FIGS. 3A and 3B, cross-sectional illustrations of electronic packages 300 with vertically oriented inductors 320 (i.e., a single turn inductor in FIG. 3A and a multi-turn inductor in FIG. 3B) are shown, in accordance with various embodiments. In FIG. 3A and FIG. 3B, the inductors 320 are embedded in a package substrate 315. The package substrate 315 may be an organic package substrate. For example, the package substrate 315 may comprise a plurality of build-up layers stacked over each other. That is, each layer of the inductor 320 may be embedded in a layer of the package substrate 315.

Referring now to FIG. 3A, a cross-sectional illustration of an electronic package 300 with a vertically oriented single turn inductor 320 is shown, in accordance with an embodiment. In an embodiment, the inductor 320 may comprise a first trace 321. The first trace 321 may have a first end 326 and a second end 327. The first trace 321 may be positioned over a layer of the package substrate 315. In some embodiments, the layer is the first layer of a package substrate, or the layer may have one or more underlying layers. In other embodiments, the first trace 321 may be positioned over a core of an electronic package 300.

In an embodiment, a first conductive path 323 may extend up from the first end 326 of the first trace 321, and a second conductive path 322 may extend up from the second end 327 of the first trace 321. In an embodiment, the first conductive path 323 and the second conductive path 322 may comprise alternating vias 328 and pads 329. In the illustrated embodiment, the first conductive path 323 and the second conductive path 322 may pass through one or more layers of the package substrate 315. For example, the inductor 320 includes a first conductive path 323 and a second conductive path 322 that extend through three layers of the package substrate 315.

In an embodiment, a second trace 324 is positioned over the first conductive path 323, and a third trace 325 is positioned over the second conductive path 322. The second trace 324 and the third trace 325 may extend towards each other and be spaced apart by a gap G. In the illustrated embodiment, the second trace 324 and the third trace 325 are shown as being over a top layer of the package substrate 315. However, it is to be appreciated that one or more additional package layers or a resist layer may be disposed over the second trace 324 and the third trace 325.

Referring now to FIG. 3B, a cross-sectional illustration of an electronic package 300 with a vertically oriented multi-turn inductor 320 is shown, in accordance with an embodiment. In an embodiment, the first turn may comprise a first trace 332, a second trace 333, a first conductive path 341 over the second trace 333, a second conductive path 342 over the first trace 332, a third conductive trace 334 over the first conductive path 341, and a fourth conductive trace 335 over the second conductive path 342.

In an embodiment, the second turn may comprise a first via 343 over the first trace 332, a second via 344 over the second trace 333, a fifth trace 336 over the first via 343, a sixth trace 337 over the second via 344, a third via 345 over the fifth trace 336, a fourth via 346 over the sixth trace 337, and a seventh trace 338 connecting the third via 345 to the fourth via 346. In an embodiment, the second turn may include a cross-over connection 360. In order to enable the cross-over connection 360, the first via 343 and the second via may be offset from each other (as indicated by the dashed outline of the second via 344). The second via may extend up and connect to the sixth trace 337 (which passes behind the fifth trace 336, as indicated by the dashed outline).

The use of a cross-over connection 360 enables a symmetric inductor 320. That is, a centerline 316 may be shared by the first turn and the second (interior) turn of the inductor 320. Accordingly, a tap (not shown) may be made to a center of the second turn (along the seventh trace 338) and provide reductions in phase and amplitude imbalances for differential RF circuits.

In FIGS. 1A-3B, inductors, solenoids, and transformers that are vertically oriented are shown. However, embodiments are not limited to such configurations. For example, embodiments may also include planar inductors. Planar inductors in accordance with embodiments disclosed herein allow for multi-turn inductors that are symmetric. Particularly, a cross-over connection allows for symmetric multi-turn planar inductors. Such symmetric architectures are not able to be formed with conventional planar inductor solutions.

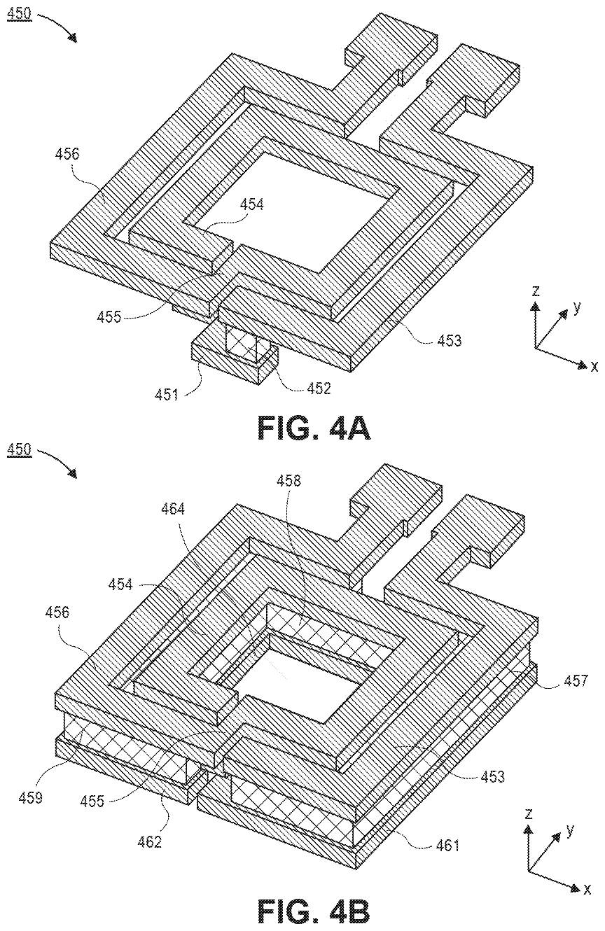

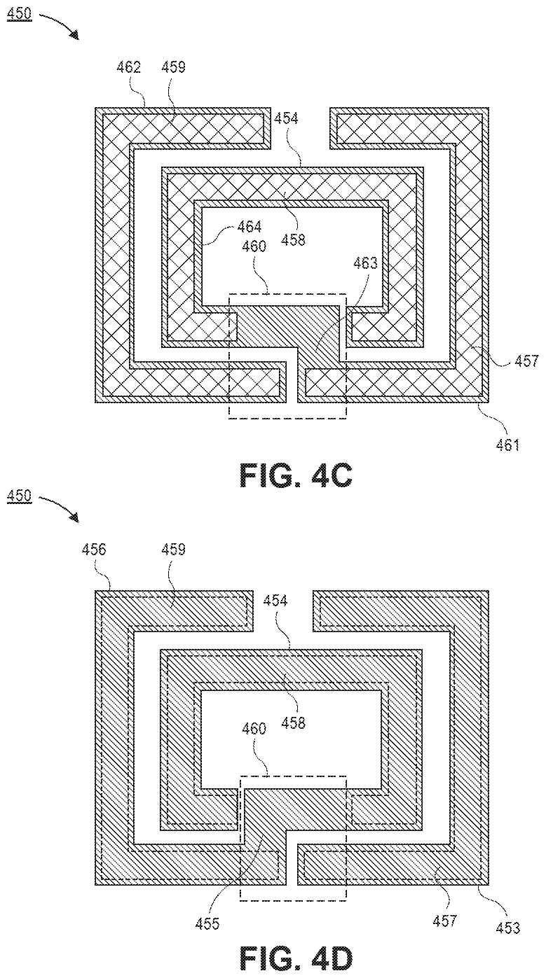

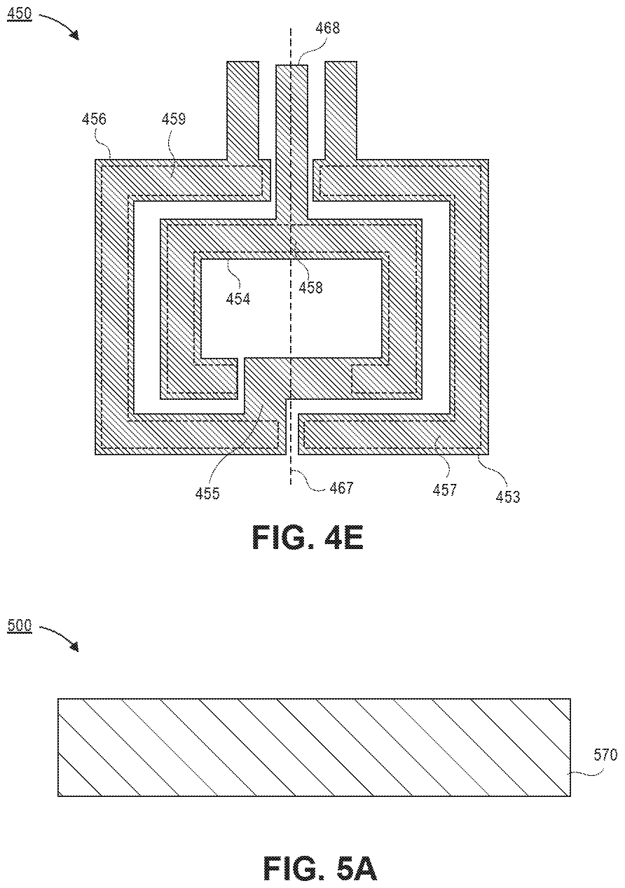

Referring now to FIG. 4A, a perspective view illustration of a multi-turn planar inductor 450 is shown, in accordance with an embodiment. In an embodiment, the inductor may comprise a first turn and a second turn within the first turn. The first turn may comprise a first trace 456 and a second trace 453. In an embodiment, the second turn may comprise a third trace 454. The first turn may be coupled to the second turn by a bridge 455. The bridge 455 may be in the same plane (i.e., the X-Y plane) as the first trace 456, the second trace 453, and the third trace 454. In order to provide an electrical connection from the second turn back out to the first turn, a connection out of the plane may be implemented. For example, vias 452 may extend down from the second trace 453 and the third trace 454 (not visible in FIG. 4A). A fourth trace 451 may connect the vias 452. Accordingly, while referred to as a planar inductor, it is to be appreciated that one or more features may extend out of the plane of the first turn and the second turn in order to provide a cross-over connection.

Referring now to FIG. 4B, a perspective view illustration of a multi-turn planar inductor 450 with lithographically defined vias is shown, in accordance with an embodiment. The use of lithographically defined vias allows for the thickness of the inductor 450 to be increased, thereby reducing the resistance and increasing the inductance. In an embodiment, the top surface of the inductor 450 may be substantially similar to the inductor 450 in FIG. 4A. For example, a first trace 456 and a second trace 453 may define an outer turn, and a third trace 454 may define an inner turn. The first trace 456 may be electrically coupled to the third trace 454 by a bridge 455.

In an embodiment, a lower portion of the inductor 450 may comprise a fourth trace 461, a fifth trace 462, and a sixth trace 464. The fourth trace 461 may be below the second trace 453, the sixth trace 464 may be below the third trace 454, and the fifth trace 462 may be below the first trace 456. In an embodiment, three trench vias may be formed between the two layers of traces. A first trench via 459 may be between the first trace 456 and the fifth trace 462, a second trench via 457 may be between the second trace 453 and the fourth trace 461, and a third trench via 458 may be between the third trace 454 and the sixth trace 464.

Referring now to FIGS. 4C and 4D, plan view illustrations of various layers of the planar inductor 450 are shown, in order to more clearly illustrates aspects of certain embodiments.

Referring now to FIG. 4C, a plan view illustration of the lower layer and the trench vias of the inductor 450 is shown, in accordance with an embodiment. As shown, the fifth trace 462 is isolated from other traces on the first layer. The first trench via 459 may be over the fifth trace 462 and extend substantially along the length of the fifth trace 462. In an embodiment, the fourth trace 461 may be electrically coupled to the sixth trace 464 by a bridge 463. As shown, the third trench via 458 is over the sixth trace 464 and extends along the length of the sixth trace 464. However, a portion of the sixth trace 464 remains uncovered by the third trench via 458 in the cross-over region 460. This opening above the sixth trace 464 allows for the cross-over connection in the next layer to be implemented. In an embodiment, the second trench via 457 is over the fourth trace 461, and extends substantially along the length of the fourth trace 461.

Referring now to FIG. 4D, a plan view illustration of a second layer of the planar inductor 450 is shown, in accordance with an embodiment. As shown, the bridge 455 of the second layer provides the electrical connection from the first trace 456 to the third trace 454. The bridge 455 passes through the cross-over region 460 where there is a gap in the trench vias. Accordingly, a thick planar inductor 450 may be provided with only a small region where the effective thickness is reduced (i.e., since the trench via is absent).

Furthermore, the multi-turn planar inductors 450 in accordance with embodiments disclosed herein are symmetric. As shown, in FIG. 4E, the inductor 450 comprises a centerline 467 that is along the center point of the outer turn and the inner turn. Accordingly, a tap 468 may be made to the inner turn. For example, tap 468 may be made to the third trace 454. The central positioning of the tap 468 is both the physical and the electrical center of the inductor and therefore provides reductions in phase and amplitude imbalances for differential RF circuits.

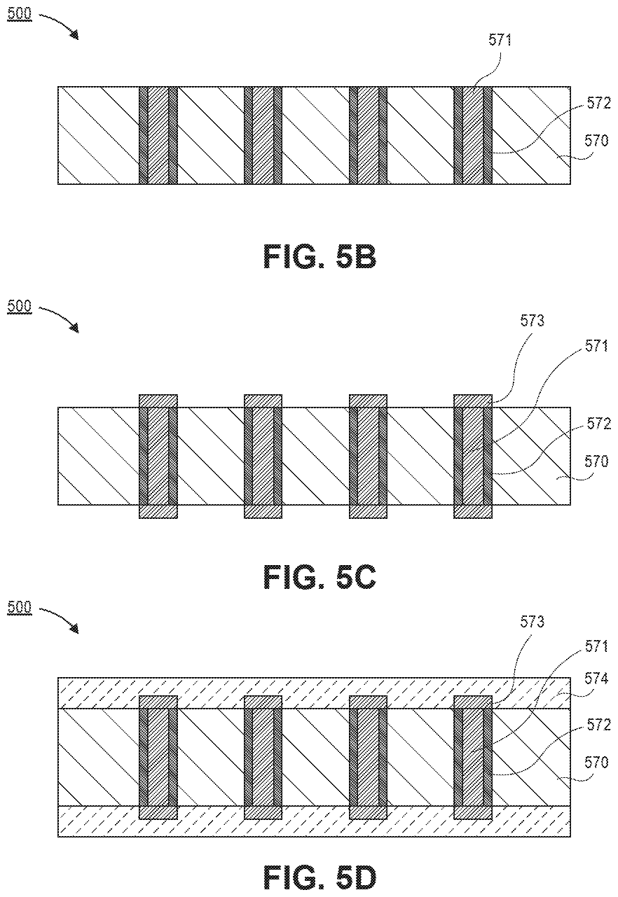

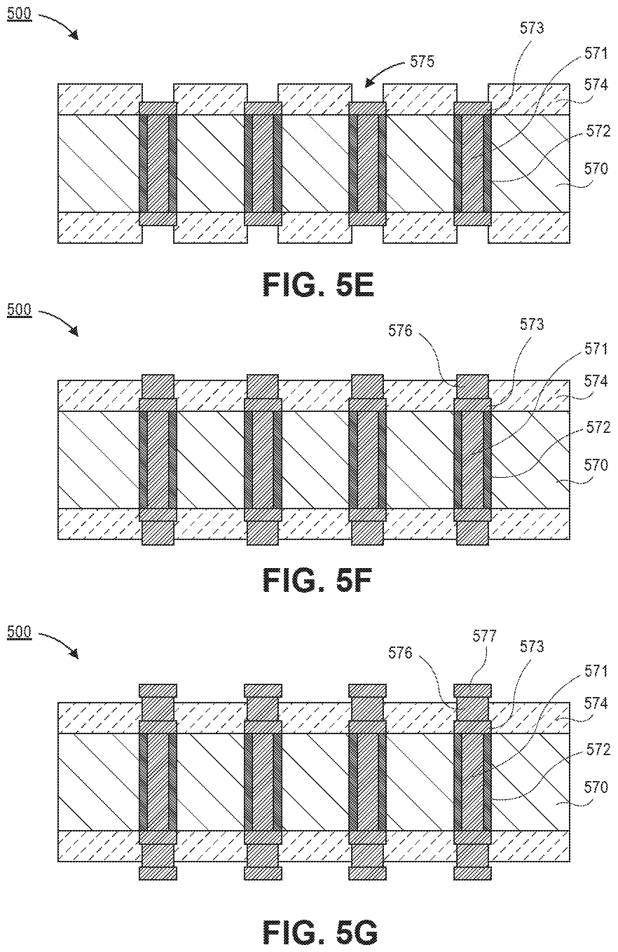

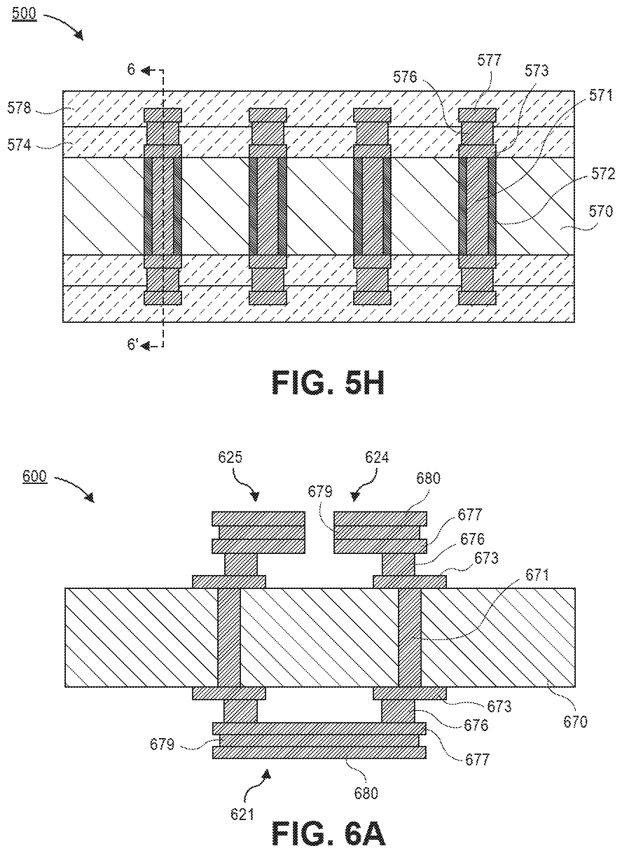

Referring now to FIGS. 5A-5H, a series of cross-sectional illustrations depicting a process for fabricating an electronic package 500 with vertically oriented inductors through a package core layer 570 is shown, in accordance with an embodiment.

Referring now to FIG. 5A, a cross-sectional illustration of a core 570 of an electronic package 500 is shown, in accordance with an embodiment. In an embodiment, the core 570 may be any suitable core material. In a particular embodiment, the core 570 is a glass substrate. The glass substrate may be a photo-definable glass substrate in some embodiments. The use of a photo-definable glass substrate may allow for fine pitch vias. For example, subsequently formed vias may have a diameter of approximately 20 μm or less with a pitch of approximately 30 μm or less.

Referring now to FIG. 5B, a cross-sectional illustration after a plurality of through core vias 571 are disposed through the core 570 is shown, in accordance with an embodiment. In an embodiment, the vias 571 may include a lining 572, as is known in the art. For example, the via openings may be formed with an etching process, and the vias 571 may be copper plugs.

Referring now to FIG. 5C, a cross-sectional illustration after a first metal layer 573 is disposed over the core 570 and vias 571 is shown, in accordance with an embodiment. The first metal layer 573 may be patterned with an etching process or the like. In some embodiments, the first metal layer 573 may be omitted if no trace is desired to be formed directly on the core 570.

Referring now to FIG. 5D, a cross-sectional illustration after a first dielectric layer 574 is disposed over the first metal layer 573 is shown, in accordance with an embodiment. In an embodiment, the first dielectric layer 574 may be disposed with a lamination process or the like.

Referring now to FIG. 5E, a cross-sectional illustration after trench via openings 575 are formed into the first dielectric layer 574 is shown, in accordance with an embodiment. In an embodiment, the via openings 575 may be lithographically defined. As such, the via openings 575 may extend along the length of the traces in the first metal layer (i.e., into and out of the plane of FIG. 5E).

Referring now to FIG. 5F, a cross-sectional illustration after trench vias 576 are disposed in the via openings 575 is shown, in accordance with an embodiment. In an embodiment, the trench vias 576 may be disposed with a plating process, such as electroless plating or the like.

Referring now to FIG. 5G, a cross-sectional illustration after a second metal layer 577 is disposed over the trench vias 576 is shown, in accordance with an embodiment. In an embodiment, the second metal layer 577 may be deposited and patterned to form traces that substantially cover the trench vias 576.

Referring now to FIG. 5H, a cross-sectional illustration after a second dielectric layer 578 is disposed over the second metal layer 577 is shown, in accordance with an embodiment. In an embodiment, the second dielectric layer 578 may be laminated or the like. Subsequent dielectric layers, circuitry (e.g., traces, pads, vias, etc.), and the like may then be fabricated above the inductors.

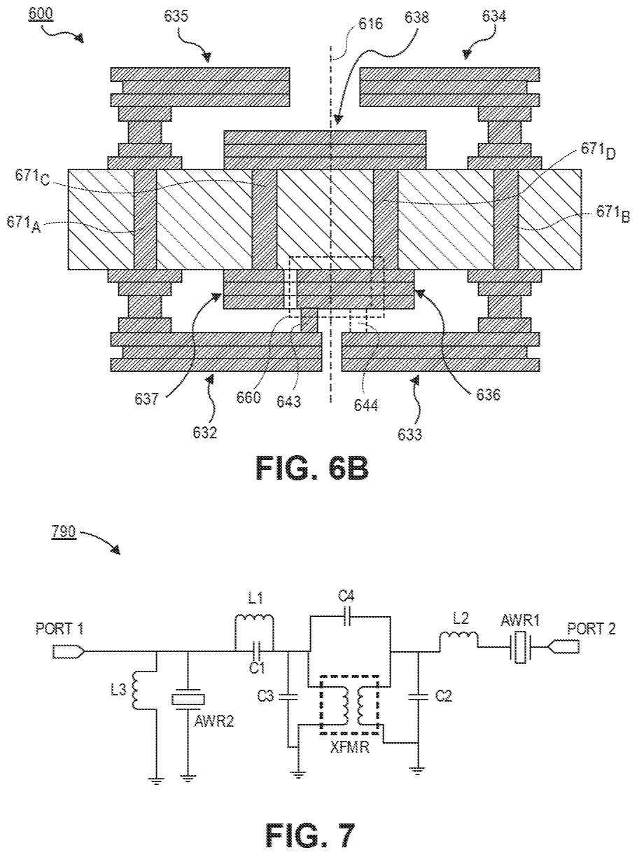

Referring now to FIGS. 6A and 6B, cross-sectional illustrations of inductors along line 6-6′ in FIG. 5H are shown, in accordance with various embodiments. In FIG. 6A, a single turn inductor is shown. In FIG. 6B, a multi-turn inductor is shown. In FIGS. 6A and 6B, the dielectric layers above the core 670 are omitted for simplicity. However, it is to be appreciated that one or more dielectric layers may be disposed over the surfaces of the core 670, similar to what is shown in FIGS. 5A-5H.

Referring now to FIG. 6A, a cross-sectional illustration of a package 600 with a vertically oriented single turn inductor that passes through the core 670 is shown, in accordance with an embodiment. In an embodiment, the core 670 may comprise a pair of through core vias 671. Over a bottom surface of the core 670 the through core vias 671 may be electrically coupled by a conductive path. For example, the conductive path may include pads 673, vias 676, and a bridge 621. The bridge 621 may comprise a first trace 677, a trench via 679 over the first trace 677, and a second trace 680 over the trench via 679. However, other embodiments may also include a bridge 621 that comprises only a single trace.

Over the top surface of the core 670, one of the vias 671 may be coupled to a pad 673, via 676, and a conductive path 624. The conductive path 624 may comprise a first trace 677, a trench via 679 over the first trace 677, and a second trace 680 over the trench via 679. In an embodiment, the other one of the vias 671 may be coupled to a pad 673, via 676, and a conductive path 625. The conductive path 625 may comprise a first trace 677, a trench via 679 over the first trace 677, and a second trace 680 over the trench via 679. While conductive paths 624 and 625 are shown as stacks, it is to be appreciated that the paths may also comprise a single trace.

Referring now to FIG. 6B, a cross-sectional illustration of an electronic package 600 with a multi-turn inductor through the core 670 is shown, in accordance with an embodiment. In an embodiment, the inductor may include an outer turn that comprises a first conductive path 632, a second conductive path 633, a first via 671_{A}, a second via 671_{B}, a third conductive path 635, and a fourth conductive path 634. In an embodiment, the inner turn of the inductor may comprise a fifth conductive path 636, a sixth conductive path 637, a third via 671_{C}, a fourth via 671_{D}, and a seventh conductive path 638.

In an embodiment, the outer turn may be electrically coupled to the inner turn by a cross-over connection 660. The cross-over connection 660 may comprise a first via 643 that couples the first conductive path 632 to the fifth conductive path 636, and a second via 644 that couples the second conductive path 633 to the sixth conductive path 637. As indicated by the dashed lines, the second via 644 may be offset from the first via 643. In an embodiment, the cross-over connection 660 may be similar to the cross-over connection 360 illustrated in FIG. 3B.

In an embodiment, the inductor in electronic package 600 is symmetric. That is, a centerline 616 may be the centerline of the outer turn and the inner turn. Accordingly, a tap (not shown) may be made to the inner loop at a center point of seventh conductive path 638 to provide reductions in phase and amplitude imbalances for differential RF circuits.

Referring now to FIG. 7, a schematic illustration of a filter 790 that may include symmetric inductors, solenoids, and/or transformers in accordance with embodiments disclosed herein is shown. As shown, the filter 790 comprises a plurality of inductors L1-L3, a plurality of capacitors C1-C4, a plurality of acoustic wave resonators AWR1-AWR2, and a transformer XFMR. The number of components and the specific circuit formed with the components is exemplary in nature, and embodiments are not limited to configurations illustrated in FIG. 7.

In an embodiment, the inductors L1-L3 may comprise vertically oriented single turn inductors, vertically oriented multi-turn inductors, and/or symmetric planar inductors, in accordance with embodiments disclosed herein. In an embodiment, the transformer XFMR may comprise a pair of single turn inductors, vertically oriented multi-turn inductors, and/or symmetric planar inductors, in accordance with embodiments disclosed herein. In an embodiment, the transformer XFMR may have a 1:1 impedance transformation ratio. However, it is to be appreciated that other impedance transformation ratios are also possible by changing dimensions of one of the inductors in the XFMR.

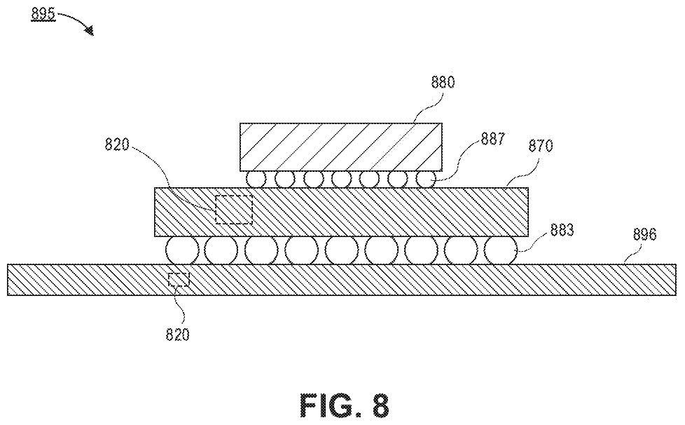

Referring now to FIG. 8, a cross-sectional illustration of a packaged system 895 is shown, in accordance with an embodiment. In an embodiment, the packaged system 895 may include a die 880 electrically coupled to a package substrate 870 with solder bumps 887. In additional embodiments, the die 880 may be electrically coupled to the package substrate 870 with any suitable interconnect architecture, such as wire bonding or the like. The package substrate 870 may be electrically coupled to a board 896, such as a printed circuit board (PCB) with solder bumps 883 or any other suitable interconnect architecture, such as wire bonding or the like.

In an embodiment, an inductor, solenoid, and/or transformer 820 similar to embodiments described above may be integrated into the package substrate 870 or the board 896, or the package substrate 870 and the board 896. Embodiments include any number of inductors, solenoids, and/or transformers 820 formed into the package substrate 870 and the board 896. For example, a plurality of inductors, solenoids, and/or transformers 820 may be integrated into the circuitry of the package substrate 870 or the board 896, or the package substrate 870 and the board 896 for power management, filtering, or any other desired use.

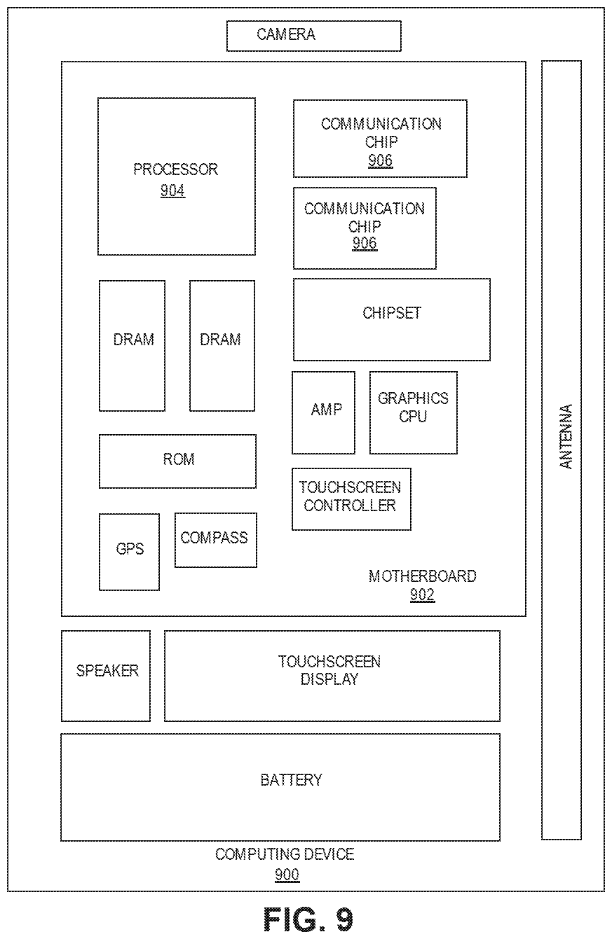

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor may be packaged in an electronic system that comprises a package substrate with inductors, solenoids, and/or transformers, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip may be packaged in an electronic system that comprises a package substrate with inductors, solenoids, and/or transformers, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an inductor, comprising: a first trace, wherein the first trace has a first end and a second end, and wherein the first trace extends along a first plane; a first conductive path over the first end of the first trace, wherein the first conductive path extends along a second plane that is substantially orthogonal to the first plane; a second conductive path over the second end of the first trace, wherein the second conductive path extends along a third plane that is substantially parallel to the second plane; a second trace over the first conductive path, wherein the second trace extends along a fourth plane that substantially parallel to the first plane; and a third trace over the second conductive path, wherein the third trace extends along the fourth plane.

Example 2: the inductor of Example 1, wherein a gap is positioned between an end of the second trace and an end of the third trace.

Example 3: the inductor of Example 1 or Example 2, wherein the first conductive path comprises alternating pads and vias, and wherein the second conductive path comprises alternating pads and vias.

Example 4: the inductor of Examples 1-3, wherein the first trace, the first conductive path, the second conductive path, the second trace, and the third trace provide an open conductive loop.

Example 5: the inductor of Examples 1-4, wherein the inductor is embedded in an organic substrate.

Example 6: a multi-turn inductor, comprising: a first turn; and a second turn within the first turn, wherein a centerline of the first turn and a centerline of the second turn are aligned.

Example 7: the multi-turn inductor of Example 6, wherein the first turn comprises: a first trace on a first plane; a second trace on the first plane, wherein a gap is between an end of the first trace and an end of the second trace; a first conductive path over the first trace, wherein the first conductive path is orthogonal to the first plane; a second conductive path over the second trace, wherein the second conductive path is orthogonal to the first plane; a third trace over the first conductive path, wherein the third trace is on a third plane that is parallel to the first plane; and a fourth trace over the second conductive path, wherein the fourth trace is on the third plane.

Example 8: the multi-turn inductor of Example 7, wherein the second turn comprises: a first via on the first trace; a second via on the second trace; a fifth trace over the first via, wherein the fifth trace extends over the gap between the end of the first trace and the end of the second trace; a sixth trace over the second via, wherein the sixth trace extends over the gap between the end of the first trace and the end of the second trace; a third via over the sixth trace; a fourth via over the fifth trace; and a seventh trace over the third via and the fourth via.

Example 9: the multi-turn inductor of Example 7 or Example 8, further comprising: a second gap between the fifth trace and the sixth trace.

Example 10: the multi-turn inductor of Examples 7-9, wherein a surface of the fifth trace is complimentary to a surface of the sixth trace.

Example 11: the multi-turn inductor of Examples 7-10, wherein the fifth trace and the sixth trace are L-shaped.

Example 12: the multi-turn inductor of Examples 7-11, wherein the first turn is aligned along a first plane and the second turn substantially aligned along the first plane.

Example 13: the multi-turn inductor of Examples 7-12, wherein the second turn is electrically coupled to the first turn with a cross-over connection that extends out of the first plane.

Example 14: the multi-turn inductor of Examples 7-13, wherein the multi-turn inductor is symmetric.

Example 15: the multi-turn inductor of Examples 7-14, wherein the multi-turn inductor is embedded in an organic substrate.

Example 16: the multi-turn inductor of Examples 7-15, further comprising: a plurality of first turn and second turn pairs, wherein the first turn and second turn pairs are connected in series to each other and aligned along parallel planes to form a solenoid.

Example 17: an electronic package, comprising: a package substrate having a first surface, a second surface opposite the first surface, and sidewall surfaces coupling the first surface to the second surface, wherein the first surface is oriented along a first plane; and a first inductor embedded in the package substrate, wherein the first inductor comprises a first turn, wherein the first turn is oriented along a second plane that is substantially orthogonal to the first plane.

Example 18: the electronic package of Example 17, wherein the first inductor further comprises a second turn that is oriented along the second plane.

Example 19: the electronic package of Example 17 or Example 18, wherein the second turn is electrically coupled to the first turn with a cross-over connection that extends out of the second plane.

Example 20: the electronic package of Examples 17-19, further comprising: a second inductor, wherein the second inductor comprises a turn that is oriented along a third plane that is substantially parallel to the second plane.

Example 21: the electronic package of Examples 17-20, wherein the first inductor and the second inductor are a transformer.

Example 22: the electronic package of Examples 17-21, wherein the first inductor is a solenoid.

Example 23: an electronic system, comprising: a board; an electronic package electrically coupled to the board, wherein the electronic package comprises: a package substrate having a first surface, a second surface opposite the first surface, and sidewall surfaces coupling the first surface to the second surface, wherein the first surface is oriented along a first plane; and a first inductor embedded in the package substrate, wherein the first inductor comprises a first turn, wherein the first turn is oriented along a second plane that is substantially orthogonal to the first plane; and a die electrically coupled to the electronic package.

Example 24: the electronic system of Example 23, wherein the first inductor is a component of a radio frequency front end (RFFE).

Example 25: the electronic system of Example 23 or Example 24, wherein the first inductor further comprises a second turn oriented along the second plane, and wherein the second turn is electrically coupled to the first turn with a cross-over connection that extends out of the second plane.

What is claimed is:

1. An inductor, comprising:
a first trace, wherein the first trace has a first end and a second end, and wherein the first trace extends along a first plane;
a first conductive path over the first end of the first trace, wherein the first conductive path extends along a second plane that is substantially orthogonal to the first plane;
a second conductive path over the second end of the first trace, wherein the second conductive path extends along a third plane that is substantially parallel to the second plane;
a second trace over the first conductive path, wherein the second trace extends along a fourth plane that substantially parallel to the first plane; and
a third trace over the second conductive path, wherein the third trace extends along the fourth plane.

2. The inductor of claim 1, wherein a gap is positioned between an end of the second trace and an end of the third trace.

3. The inductor of claim 1, wherein the first conductive path comprises alternating pads and vias, and wherein the second conductive path comprises alternating pads and vias.

4. The inductor of claim 1, wherein the first trace, the first conductive path, the second conductive path, the second trace, and the third trace provide an open conductive loop.

5. The inductor of claim 1, wherein the inductor is embedded in an organic substrate.

6. A multi-turn inductor, comprising:
a first turn; and
a second turn within the first turn, wherein a centerline of the first turn and a centerline of the second turn are aligned.

7. The multi-turn inductor of claim 6, wherein the first turn comprises:
a first trace on a first plane;
a second trace on the first plane, wherein a gap is between an end of the first trace and an end of the second trace;
a first conductive path over the first trace, wherein the first conductive path is orthogonal to the first plane;
a second conductive path over the second trace, wherein the second conductive path is orthogonal to the first plane;
a third trace over the first conductive path, wherein the third trace is on a third plane that is parallel to the first plane; and
a fourth trace over the second conductive path, wherein the fourth trace is on the third plane.

8. The multi-turn inductor of claim 7, wherein the second turn comprises:
a first via on the first trace;
a second via on the second trace;
a fifth trace over the first via, wherein the fifth trace extends over the gap between the end of the first trace and the end of the second trace;
a sixth trace over the second via, wherein the sixth trace extends over the gap between the end of the first trace and the end of the second trace;
a third via over the sixth trace;
a fourth via over the fifth trace; and
a seventh trace over the third via and the fourth via.

9. The multi-turn inductor of claim 8, further comprising:
a second gap between the fifth trace and the sixth trace.

10. The multi-turn inductor of claim 9, wherein a surface of the fifth trace is complimentary to a surface of the sixth trace.

11. The multi-turn inductor of claim 10, wherein the fifth trace and the sixth trace are L-shaped.

12. The multi-turn inductor of claim 6, wherein the first turn is aligned along a first plane and the second turn substantially aligned along the first plane.

13. The multi-turn inductor of claim 12, wherein the second turn is electrically coupled to the first turn with a cross-over connection that extends out of the first plane.

14. The multi-turn inductor of claim 6, wherein the multi-turn inductor is symmetric.

15. The multi-turn inductor of claim 6, wherein the multi-turn inductor is embedded in an organic substrate.

16. The multi-turn inductor of claim 6, further comprising:
a plurality of first turn and second turn pairs, wherein the first turn and second turn pairs are connected in series to each other and aligned along parallel planes to form a solenoid.

17. An electronic package, comprising:
a package substrate having a first surface, a second surface opposite the first surface, and sidewall surfaces coupling the first surface to the second surface, wherein the first surface is oriented along a first plane; and
a first inductor embedded in the package substrate, wherein the first inductor comprises a first turn, wherein the first turn is oriented along a second plane that is substantially orthogonal to the first plane.

18. The electronic package of claim 17, wherein the first inductor further comprises a second turn that is oriented along the second plane.

19. The electronic package of claim 18, wherein the second turn is electrically coupled to the first turn with a cross-over connection that extends out of the second plane.

20. The electronic package of claim 17, further comprising:
a second inductor, wherein the second inductor comprises a turn that is oriented along a third plane that is substantially parallel to the second plane.

21. The electronic package of claim 20, wherein the first inductor and the second inductor are a transformer.

22. The electronic package of claim 17, wherein the first inductor is a solenoid.

23. An electronic system, comprising:
a board;
an electronic package electrically coupled to the board, wherein the electronic package comprises:
a package substrate having a first surface, a second surface opposite the first surface, and sidewall surfaces coupling the first surface to the second surface, wherein the first surface is oriented along a first plane; and
a first inductor embedded in the package substrate, wherein the first inductor comprises a first turn, wherein the first turn is oriented along a second plane that is substantially orthogonal to the first plane; and
a die electrically coupled to the electronic package.

24. The electronic system of claim 23, wherein the first inductor is a component of a radio frequency front end (RFFE).

25. The electronic system of claim 23, wherein the first inductor further comprises a second turn oriented along the second plane, and wherein the second turn is electrically coupled to the first turn with a cross-over connection that extends out of the second plane.
